(19) United States
(12) Patent Application Publication
(10) Pub. No.: US 2025/0359270 A1
(43) Pub. Date: Nov. 20, 2025

(54) MOS GATE STRUCTURE WITH DUMMY THERMAL VIA

(71) Applicant: GLOBALFOUNDRIES U.S. Inc., Malta, NY (US)

(72) Inventors: Oscar D. RESTREPO, Halfmoon, NY (US); Vibhor JAIN, Clifton Park, NY (US); Anupam DUTTA, Kolkota (IN); Rui Tze TOH, Singapore (SG); Vvss Satyasuresh CHOPPALLI, Bengaluru (IN)

(21) Appl. No.: 18/664,185

(22) Filed: May 14, 2024

(51) Int. Cl. H01L 29/423; H01L 29/06; H01L 29/66; H01L 29/78

(52) U.S. Cl. CPC H10D 64/511; H10D 30/0281; H10D 30/65; H10D 62/10

(57) ABSTRACT

A semiconductor device includes a semiconductor substrate, a gate structure on the semiconductor substrate, the gate structure comprising a source region, a drain region, and a gate electrode, and at least one thermally conductive electrical insulator pillar in contact with the gate structure, wherein the at least one thermally conductive electrical insulator pillar extends from the gate structure to a back end of line (BEOL) layer of the semiconductor device.

### BACKGROUND

Heat dissipation is an important aspect in the design of semiconductor devices. Power used by semiconductors creates heat which must be removed from the device to avoid over-heating, but how to do this efficiently is a growing challenge. The challenge is increasing as semiconductor devices become more highly integrated, handle higher amounts of power, and is especially acute for three-dimensional integrated circuits in which two or more chips are stacked on one another.

Interlayer dielectric materials tend to have low thermal conductivity. For example, silicon dioxide has a thermal conductivity of around 1 W/(m*K), which limits the extent to which heat generated in the active layer of the chip can dissipate. This can lead to excessive heat build-up at the active layer, limiting the performance of the chip and possibly leading to errors or failure.

### SUMMARY

Embodiments of the present application relate to a semiconductor device and a method for forming a semiconductor device. The semiconductor device may include a gate structure and at least one thermally conductive electrical insulator pillar in contact with the gate structure.

In an embodiment, a semiconductor device includes a semiconductor substrate, a gate structure on the semiconductor substrate, the gate structure comprising a source region, a drain region, and a gate electrode, and at least one thermally conductive electrical insulator pillar in contact with the gate structure. The at least one thermally conductive electrical insulator pillar extends from the gate structure to a back end of line (BEOL) layer of the semiconductor device.

In an embodiment, a semiconductor device includes a semiconductor substrate, an asymmetric gate structure on the semiconductor substrate, the asymmetric gate structure comprising a gate electrode, a source region on a source side of the gate electrode, and an extended drain region on a drain side of the gate electrode, and a thermally conductive electrical insulator pillar on the drain side of the gate structure and in contact with the gate structure. The thermally conductive electrical insulator pillar extends from the gate structure to a BEOL layer of the semiconductor device.

In an embodiment, a method for forming a semiconductor device includes forming a gate structure on the semiconductor substrate, the gate structure comprising a source region, a drain region, and a gate electrode, and forming at least one thermally conductive electrical insulator pillar in contact with the gate structure and extending from the gate structure to a BEOL layer of the semiconductor device.

### BRIEF DESCRIPTION OF THE DRAWINGS

FIG. 1 illustrates an embodiment of a semiconductor device with thermally conductive electrical insulator pillars.

FIG. 2 is a plan view of an embodiment of a semiconductor device in which a single thermally conductive electrical insulator pillar is associated with each gate structure.

FIG. 3A is a cross-sectional view of an embodiment of an extended drain metal oxide semiconductor (EDMOS) gate structure in which a thermally conductive electrical insulator pillar contacts a capping layer on the drain side of the gate structure.

FIG. 3B is a cross-sectional view of an embodiment of an EDMOS gate structure in which a thermally conductive electrical insulator pillar contacts a spacer layer on the drain side of the gate structure.

FIG. 3C is a cross-sectional view of an embodiment of an EDMOS gate structure in which a thermally conductive electrical insulator pillar contacts a drain region of the gate structure.

FIG. 4 is a cross-sectional view of an embodiment of a lateral double-diffused metal oxide semiconductor (LDMOS) gate structure in which a thermally conductive electrical insulator pillar is buried in a shallow trench isolation (STI) structure.

FIG. 5 is a plan view of an embodiment of a semiconductor device in which two thermally conductive electrical insulator pillars are associated with each gate structure.

FIG. 6 is a cross-sectional view of a symmetrical gate structure in which a thermally conductive electrical insulator pillar is in contact with spacers on both sides of the gate structure.

FIGS. 7A and 7B illustrate embodiments of semiconductor devices with thermally conductive electrical insulator pillars coupled to BEOL structures.

FIG. 8 is a plan view of a layout of metal lines which are coupled to thermally conductive electrical insulator pillars.

### DETAILED DESCRIPTION

A detailed description of embodiments is provided below along with accompanying figures. The scope of this disclosure is limited by the claims and encompasses numerous alternatives, modifications and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured. The figures are not drawn to scale, and features are enlarged or diminished for visual clarity.

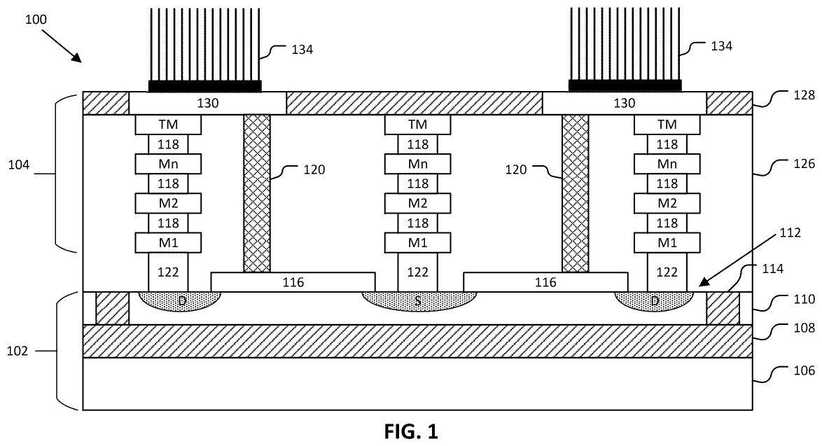

FIG. 1 illustrates an embodiment of a semiconductor device 100 comprising a semiconductor substrate 102. In the embodiment of FIG. 1, the semiconductor substrate 102 is a silicon on insulator (SOI) substrate with a bulk semiconductor layer 106, a buried oxide (BOX) layer 108, and a silicon device layer 110 over the BOX layer 108.

Semiconductor substrates 102 according to the present disclosure are not limited to being SOI substrates. In other embodiments, the substrate 102 may be another type such as a silicon germanium substrate, a gallium nitride substrate, a silicon substrate, or another substrate material as known in the art. The insulator layer of a SOI substrate provides thermal insulation which can trap heat in a device 100, so embodiments can be especially effective for SOI substrates.

The SOI substrate of FIG. 1 includes an active region 112 on which active devices are formed. The active region 112 includes active components or circuits, such as conductive features, implantation regions, resistors, capacitors, and other semiconductor elements, e.g., transistors, diodes, etc. The active region 112 is bounded by shallow trench isolation (STI) structures 114 on sides of the active region and is formed using front-end-of-line (FEOL) processes.

The active devices shown in the figure are transistors with gate structures 116 coupled to a source region S and a drain region D. The gate structures 116 may be conventional gates as known in the art, e.g. polysilicon gates separated from the source and drain regions by a gate dielectric material. In some implementations, the transistors may be used for power amplifiers and operate at voltages of 10V or more. For example, the transistors may be used for high power switching operations using a voltage of from 24 to 30 volts. In other embodiments, the transistors may operate at voltages (VDD) of from 3.3V to 5V.

The gate structures 116 may include one or more known gate material such as polysilicon or silicide, or a metal or metal composite such as tungsten, a nitride of tungsten or titanium, etc. As will be explained in more detail below, the gate structures 116 may be symmetrical gates, or asymmetrical gates such as extended drain metal oxide semiconductor (EDMOS) gates or lateral double-diffused metal oxide semiconductor (LDMOS) gates.

Also shown in FIG. 1 are metal lines of metal layers M1-Mn and a top metal layer TM, each corresponding to a back end of line (BEOL) metal layer. Each of the metal lines of metal layers M1-TM is coupled to a vertically adjacent metal line by a via 118, which may be interlayer dielectric vias (IDV) or interconnect vias (IV). Although only three specific metal layers (M1, M2 and TM) are shown, additional metal layers represented generally as Mn may be present between metal layer M2 and top metal layer TM, resulting in a total of four, five or more metal layers.

Vias 118 may be formed by etching via holes using conventional mask patterning and etch processes as known in the art and depositing a conductive material in the via holes. The metal lines and vias 118 may include conductive materials typically used in BEOL processes, such as copper, aluminum, tungsten, titanium, tantalum, nitrides of titanium or tantalum, or multiple layers or combinations thereof.

The metal layers are coupled to structures in the active region 112 by contacts 122. The contacts are formed in FEOL process using conventional contact materials. For example, the contacts 122 may include a tungsten material and a titanium nitride barrier liner layer along the sidewalls and bottoms of the contacts. Other materials and combinations of materials are possible as known in the art.

The conductive structures in the device are surrounded by an insulating material 126 (e.g. interlayer dielectric) which is a dielectric material. In some embodiments, the insulating material 126 is made of silicon oxide, although other materials are possible. In some embodiments, the insulating material 126 includes multiple layers of dielectric materials. One or more of the multiple dielectric layers may be made of low dielectric constant (low-k) materials.

In the embodiment of FIG. 1, two thermally conductive electrical insulator structures, or pillars, 120 are respectively coupled to the two gate structures 116. The thermally conductive electrical insulator pillars 120 generally have a height (e.g. top-to-bottom in the cross-sectional view of FIG. 1) that is greater than a width (e.g. side-to-side in the cross-sectional view of FIG. 1), resulting in a pillar shape. The thermally conductive electrical insulator pillars 120 may be referred to as dummy thermal vias, e.g. non-conductive structures that extend to a metal layer of a device and conduct heat.

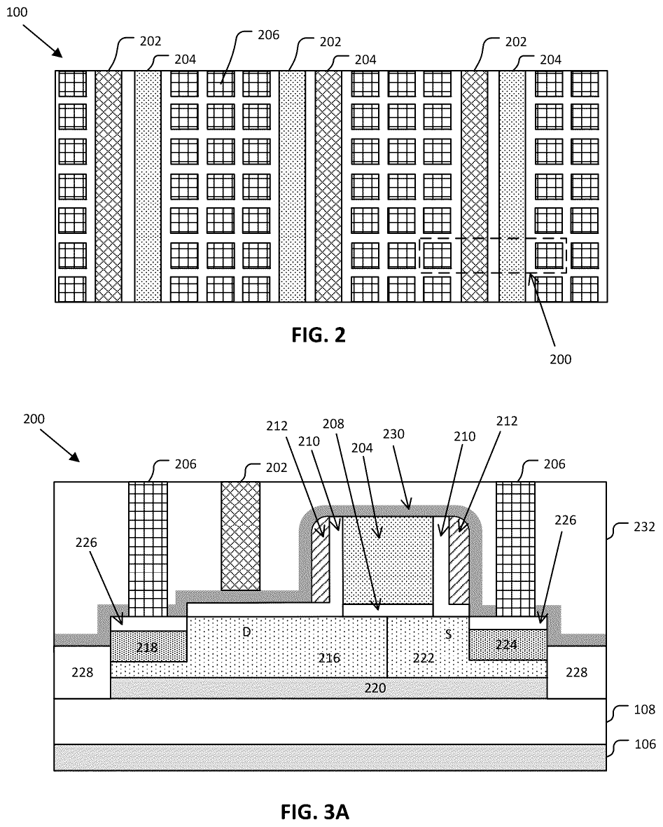

The thermally conductive electrical insulator pillars 120 may have a generally linear or fin shape in the depth dimension (e.g. front-to-back in the cross-sectional view of FIG. 1, or top to bottom in the plan view of FIG. 2), especially when the pillars 120 run parallel to a generally linear gate electrode 204. However, embodiments are not limited to having a generally linear or fin shape in the depth dimension, and in other embodiments the thermally conductive electrical insulator pillars 120 may have a circular, rectangular or square shape with respect to a plan view of the semiconductor device 100.

The thermally conductive electrical insulator pillars 120 are formed of a thermally conductive and electrically insulating material. Examples of the thermally conductive material of the thermally conductive electrical insulator pillars 120 are a carbon-based material such as diamond, a metal oxide, a metal nitride and a combination of these materials. An example of a metal oxide that may be suitable as a thermally conductive electrical insulator material is an oxide of aluminum, and an example of a metal nitride is a nitride of aluminum. The metal oxides and nitrides may include one or both of oxygen and nitrogen (as well as other non-metal materials) in stoichiometric or non-stoichiometric ratios with respect to the metal. These are only examples, and other materials are possible.

The thermally conductive electrical insulator material is a dielectric material that is also effective at transferring heat away from a gate structure 116. Exemplary materials may have a thermal conductivity of 30 W/(m*K) or greater, 150 W/(m*K) or greater, 1000 W/(m*K) or greater or 2000 W/(m*K) or greater. Because the material of the thermally conductive electrical insulator pillars 120 is a dielectric material, the pillars 120 can contact a gate structure 116 without affecting the performance of an associated transistor.

The thermally conductive electrical insulator pillars 120 may be formed using a damascene process. For example, after forming the insulating material 126, trenches defining the pillar shapes may be etched in the insulating material using an etch technique, and a thermally conductive electrical insulator material is deposited in the trenches.

Conventional thin film deposition/growth methods for diamond thin films include a downstream microwave plasma chemical vapor deposition in the 350-450 C range using carbon precursors such as a carbon-rich gas mixture. In some embodiments, the thin film diamond deposition temperature can be controlled to be below 500 C to avoid damaging or melting the on-chip metals used for wiring and vias, such as aluminum and copper. Alternatively, the thin film diamond can be deposited using atomic layer deposition at temperatures below 500 C, or using any known method. A process for depositing an oxide of aluminum, may be chemical vapor deposition (CVD), atomic layer deposition (ALD), or plasma-enhanced atomic layer deposition (PE-ALD), for example. A process for depositing a nitride of aluminum may be ALD, plasma-enhanced ALD (PE-ALD), atomic layer annealing (ALA), and CVD techniques such as pulsed CVD.

The thermally conductive electrical insulator pillars 120 may transfer heat from the gate structures 116 into the interior of the device structure and dissipate through the device, resulting in a more even temperature distribution and reducing heat concentration around the active region 112. In some embodiments, the thermally conductive electrical insulator pillars 120 transfer heat from the gate structures 116 to an exterior surface of the semiconductor device 100. For example, the thermally conductive electrical insulator pillars 120 may be thermally coupled to one or more thermally conductive contact 130, which may also be referred to as a backside contact 130.

A backside contact 130 may comprise a thermally conductive material such as copper or aluminum and be exposed on a backside surface of the semiconductor device 100. The backside contact 130 may be disposed in a backend layer 128 of the device, which may comprise one or more sealing layer formed of oxide or nitride materials, e.g. a passivation layer. In some embodiments, a backside contact 130 which is thermally coupled to one or more thermally conductive electrical insulator pillar 120 is also electrically coupled to a metal structure of top metal layer TM, and carries electrical signals to or from the semiconductor device 100. Although not shown in the figures, in some embodiments the backside contact 130 comprises a solder bump.

In the embodiment of FIG. 1, the backside contacts 130 are coupled to heat sinks 134. However, FIG. 1 is a simplified representation of a semiconductor device 100, and additional thermally conductive structures (not shown) may be present between the backside contacts 130 heat sinks 134 as known in the art. Heat sinks 134 may be packaged with the semiconductor device 100.

FIG. 2 is a plan view of an embodiment of a transistor region of a semiconductor device 100 comprising thermally conductive electrical insulator pillars 202. In the embodiment of FIG. 2, thermally conductive electrical insulator pillars 202 are arranged in parallel to gate electrodes 204, and each gate electrode 204 is paired with a single thermally conductive electrical insulator pillar 202. Also shown in the figure is an outline of a gate structure 200. Each thermally conductive electrical insulator pillar 202 may extend across multiple gate structures 200.

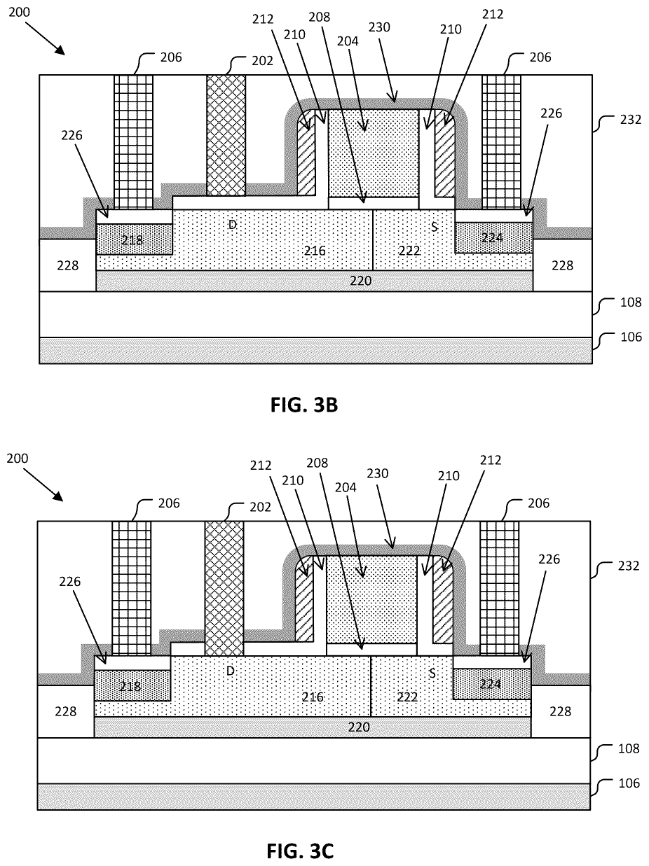

FIG. 3A is a cross-sectional view showing an embodiment of a gate structure 200 that is an asymmetrical gate. In the embodiment of FIG. 3A, the asymmetrical gate structure 200 is an extended drain metal oxide semiconductor (EDMOS) gate. In an EDMOS gate, the length of the drain region D is greater than the length of the source region S. EDMOS gates in embodiments of the present disclosure can have many different configurations, e.g. with respect to materials and the arrangement of doping regions, spacers and shallow trench isolation (STI) structures. The example in FIG. 3A is only one such non-limiting configuration.

Gate structures 200 of the present disclosure can be manufactured in a number of ways using a number of different tools. In general, though, the methodologies and tools are used to form structures with dimensions in the micrometer and nanometer scale. The techniques employed to manufacture gate structures 200 of the present disclosure have been adopted from integrated circuit (IC) technology. For example, the structures are built on wafers and are realized in films of material patterned by photolithographic processes on the top of a wafer.

In particular, the fabrication of the gate structures 200 uses three basic building blocks: (i) deposition of thin films of material on a substrate, (ii) applying a patterned mask on top of the films by photolithographic imaging, and (iii) etching the films selectively to the mask. When structures are formed using a damascene process, a material may be formed over the exposed surface, and excess material is removed using a planarization process such as chemical mechanical polishing (CMP). Doped regions may be formed using an in situ doping process and/or ion implantation. These processes are known to persons of ordinary skill in the art, and may be applied as known in the art to form gate structures of the present disclosure.

The gate structure 200 comprises a gate electrode 204 which may be a doped polysilicon material. In some embodiments, the gate electrode 204 may further comprise a metal material, e.g. a thin metal layer at the base of the electrode at the interface of the gate dielectric 208. The gate dielectric material may be silicon oxide or a high-k gate dielectric material such as hafnium oxide, aluminum oxide, tantalum oxide, titanium oxide, etc., or a combination of materials.

L-shaped spacers 210 are provided on both sides of the gate electrode 204. The L-shaped spacer 210 on the drain side of the gate extends further in a lateral direction than the L-shaped spacer 210 on the source side of the gate in accordance with the greater length of the drain region D. The L-shaped spacers 210 may comprise a dielectric material such as an oxide or nitride of silicon or a metal. Sidewall spacers 212 are formed over the L-shaped spacers 210 and may include a dielectric material such as an oxide or nitride of silicon or a metal. The material of sidewall spacers 212 may be the same or different from the material of L-shaped spacers 210. In some embodiments, dielectric spacers extending over the source and drain regions have a shape other than an L-shape; for example, spacers may have a line shape with respect to the cross-sectional view of FIG. 3A.

Drain region D of the gate structure 200 includes a first doped drain region 216 and a second doped drain region 218. The second doped drain region 218 may be a highly doped region (e.g. P+ or N+) with a higher dopant concentration than the first doped drain region 216. The dopant type (P or N) of first doped drain region 216 may be the same or different from that of the second doped drain region 218.

Source region S of the gate structure 200 includes a first doped source region 222 and a second doped source region 224. The second doped source region 224 may be a highly doped region (e.g. P+ or N+) with a higher dopant concentration than the first doped source region 222. The dopant type (P or N) of first doped source region 222 may be the same or different from that of the second doped source region 224.

A deep well 220 is located under the first drain doped region 216 and the first doped source region 222. The deep well 220 may have dopants of either type, P or N.

In one specific embodiment, the first doped drain region 216 has N+ doping, the second doped drain region 218 has P doping, the first doped source region 222 has N+ doping, the second doped source region 224 has P doping, and the deep well 220 has N doping. In another specific embodiment, the first doped drain region 216 has P+ doping, the second doped drain region 218 has P doping, the first doped source region 222 has P+ doping, the second doped source region 224 has N doping, and the deep well 220 has N doping. However, these are only examples, and other embodiments are possible.

Contacts 206 are coupled to source and drain regions S and D via silicide 226, and STI structures 228 are located on sides of the second doped drain region 218 and the second doped source region 224. A capping layer 230 is disposed over the STI structures 228, silicide 226, L-shaped spacers 210, sidewall spacers 212 and gate electrode 204, and an insulation layer 232 fills spaces between the capping layer, contacts 206 and pillar 202. The capping layer 230 may comprise a capping material such as silicon nitride. In the embodiment of FIG. 3A, the thermally conductive electrical insulator pillar 202 lands on the capping layer 230.

In various embodiments, the thermally conductive electrical insulator pillar 202 may be located at different depths and be in contact with different parts of the gate structure 200. For example, FIG. 3B illustrates an embodiment in which the thermally conductive electrical insulator pillar 202 passes through capping layer 230 and lands on the L-shaped spacer 210. FIG. 3C illustrates another embodiment in which the thermally conductive electrical insulator pillar 202 passes through the capping layer 230 and the L-shaped spacer 210 and lands on doped semiconductor material under the gate, e.g. the first doped drain region 216.

Accordingly, in some embodiments, the thermally conductive electrical insulator pillar 202 may be in contact with an electrically active part of a gate structure 200. Since the thermally conductive electrical insulator pillar 202 is an electrical insulator, it can be in contact with an electrically active part of a gate structure 200 without affecting transistor performance.

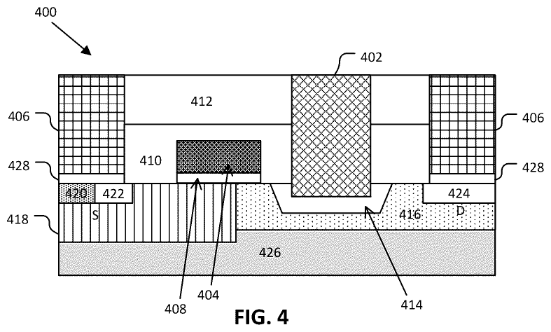

The EDMOS gate structure 200 discussed above is only one example of an asymmetric gate within the scope of the present disclosure. FIG. 4 illustrates an example of another asymmetric gate that interfaces with a thermally conductive electrical insulator pillar 402. The gate structure 400 of FIG. 4 is an LDMOS gate.

The LDMOS gate of FIG. 4 comprises a gate electrode 404 over a gate dielectric 408. The gate electrode 404 is within a gate insulation layer 410, which may be an oxide layer. The gate dielectric 408 may include the same material as gate insulation layer 410 or a different material, e.g. the materials described above with respect to gate dielectric 208. The gate insulation layer 410 may be an oxide of silicon, e.g. a tetraethyl orthosilicate (TEOS) material, formed by a LOCal Oxidation of Silicon (LOCOS) process, etc.

A first doped well 416 is located on the drain side of the transistor, and a second doped well 418 is located on the source side. The first doped well 416 may be a drift region of the LDMOS gate, and may be doped with either P or N dopants, and second doped well 418 may be doped with a different type of dopants from first doped well 416. That is, if first doped well 416 is doped with N type impurities, second doped well 418 may be doped with P type impurities, and vice versa. The first and second doped wells 416 may be formed over a semiconductor substrate 426, which may be a lightly doped substrate doped with either P or N dopants. In some embodiments, the semiconductor substrate 426 is doped with the same type of impurities as second doped well 418 of the source region of the transistor.

A first highly doped region 420 and a second highly doped region 422 are located in the source region of the LDMOS transistor, and a third highly doped region 424 is located in the drain region. The first highly doped region 420 may have a different type of impurities (e.g. N or P) than those of the second highly doped region 422, and the impurities of third highly doped region 424 may be the same type as those of the second highly doped region 422. While FIG. 4. shows exemplary shapes of doped regions, the specific number, doping types, location, shape, and doping concentrations of doped regions may vary as known in the art.

The source and drain regions of gate structure 400 are coupled to contacts 406. In some embodiments, a first contact 406, e.g. a source contact, interfaces with the first highly doped region 420 and a second highly doped region 422 via a silicide layer 428, and a second contact 406 interfaces with the third highly doped region 424 by a silicide layer 428.

In some embodiments, an STI structure 414 is located in the drift region (on the drain side) of the transistor, e.g. first doped well 416, to extend the conductive path of the LDMOS transistor. The STI structure 414 may be a single-layered or multiple-layered structure as known in the art. For example, in some embodiments the STI structure 414 may include an insulating layer and a liner layer that lines sidewalls and a base of the trench.

In the embodiment of FIG. 4, a thermally conductive electrical insulator pillar 402 is located on the drain side of the LDMOS gate structure 400. The thermally conductive electrical insulator pillar 402 extends through the upper insulation layers 410 and 412 and penetrates the upper surface of STI structure 414 such that the thermally conductive electrical insulator pillar 402 is buried within the STI structure 414. In another embodiment, the thermally conductive electrical insulator pillar 402 may land on the upper surface of the STI structure 414. In still another embodiment, the thermally conductive electrical insulator pillar 402 is located within the gate insulation layer 410, e.g. the lower surface of the pillar 402 is located between the upper and lower surfaces of gate insulation layer 410. In still another embodiment, the thermally conductive electrical insulator pillar 402 may land on the upper insulation layer 410.

The components of gate structure 400 are merely exemplary, and actual embodiments of an LDMOS gate may have more or less than the components shown in FIG. 4. For example, some embodiments may have a gate insulation layer 410 that is formed separately from second insulation layer 412 and lack an STI structure 414, while other embodiments may have a homogeneous second insulation layer that is indistinct from gate insulation layer 410 and lack an STI structure 414. Accordingly, it should be understood that FIG. 4 is representative of structures that may be present in various embodiments of an LDMOS gate structure 400.

While the asymmetrical gates of FIGS. 3A, 3B, 3C and 4 only show a single thermally conductive electrical insulator pillar for each gate structure, two or more thermally conductive electrical insulator pillars may be present in different embodiments. In embodiments, the width of a thermally conductive electrical insulator pillar on the extended or wider side of an asymmetrical gate is greater than the width of a thermally conductive electrical insulator pillar on the narrower side of the asymmetrical gate.

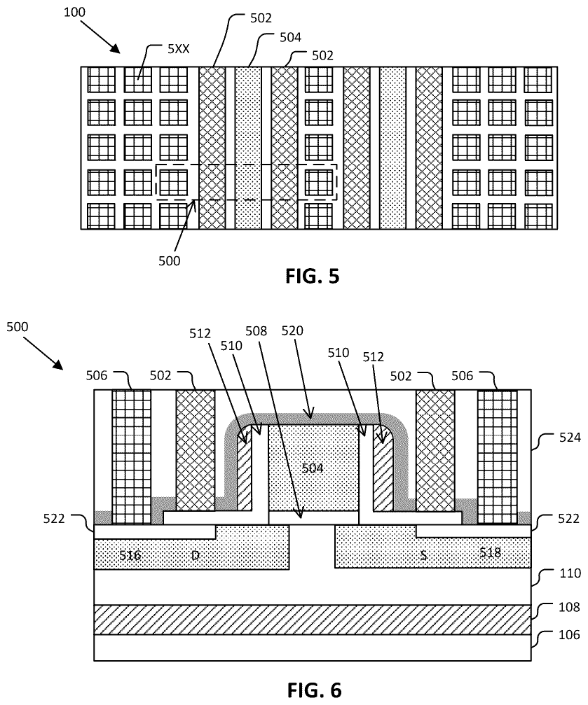

FIG. 5 is a plan view of an embodiment of a transistor region of a semiconductor device 100 comprising thermally conductive electrical insulator pillars 502. In the embodiment of FIG. 5, thermally conductive electrical insulator pillars 502 are arranged in parallel to gate electrodes 504, and a pair of thermally conductive electrical insulator pillars 502 are disposed on both sides of each gate electrode 504. Accordingly, each gate structure 500 of the embodiment of FIG. 5 is associated with two thermally conductive electrical insulator pillars 502.

FIG. 6 is a cross-sectional view showing an embodiment of a gate structure 500 that is a symmetrical gate. The gate structure 500 illustrated in FIG. 6 is a general non-limiting representation of a symmetrical gate structure with components that may be present in various embodiments.

The gate structure 500 comprises a gate electrode 504 and a gate dielectric 508 over a channel region of semiconductor substrate 110. L-shaped spacers 510 are disposed on each side of gate electrode 510 and extend across a portion of the lateral spacing between the gate electrode 504 and each contact 506. Sidewall spacers 512 are disposed over the L-shaped spacers 510, and a capping layer 520 is disposed over the spacers and gate material. A silicide 522 is located between each contact 506 and a respective doped drain region 516 and doped source region 518. The material types and forming techniques of these structures may be the same as those of corresponding structures discussed above, or as known in the art.

In the gate structure 500 of FIG. 6, a thermally conductive electrical insulator pillar 502 is located on each side of the gate electrode 504. A first thermally conductive electrical insulator pillar 502 is located between the gate electrode 504 and the source contact 506, and a second thermally conductive electrical insulator pillar 502 is located between the thermally conductive electrical insulator pillar 502 and the drain contact 506.

In some embodiments, the lower end of the thermally conductive electrical insulator pillars 502 may land on or be buried in various elements of gate structure 500 including the L-shaped spacers 510 as shown in the figure (or other shaped insulating spacing materials as known in the art), on the capping layer 520, on the silicide 522, or on portions the semiconductor substrate 110 such as the doped drain region 516 and doped source region 518. The lower end of the thermally conductive electrical insulator pillars 502 may be terminated to minimize interference with the channel region of the gate structure 500.

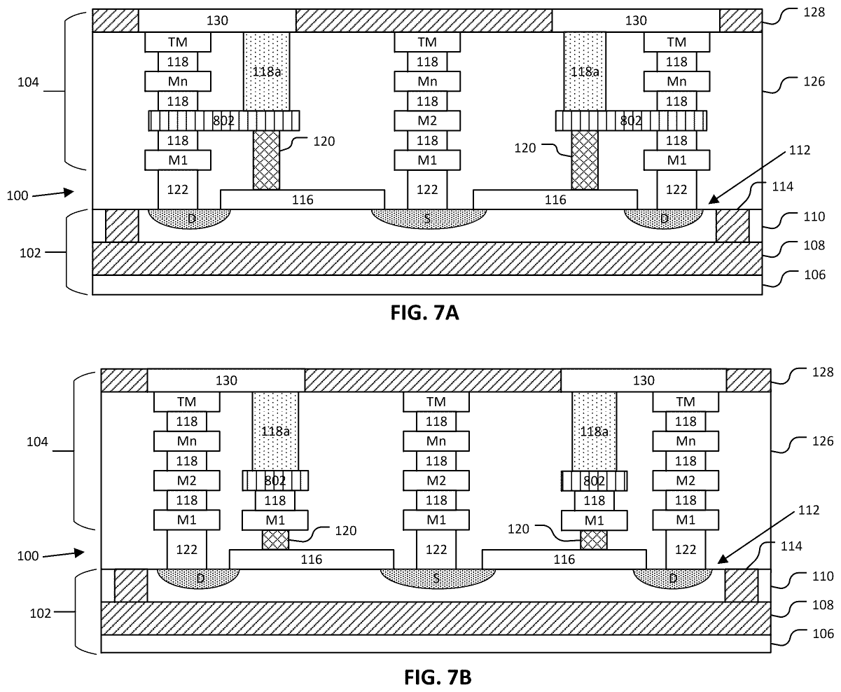

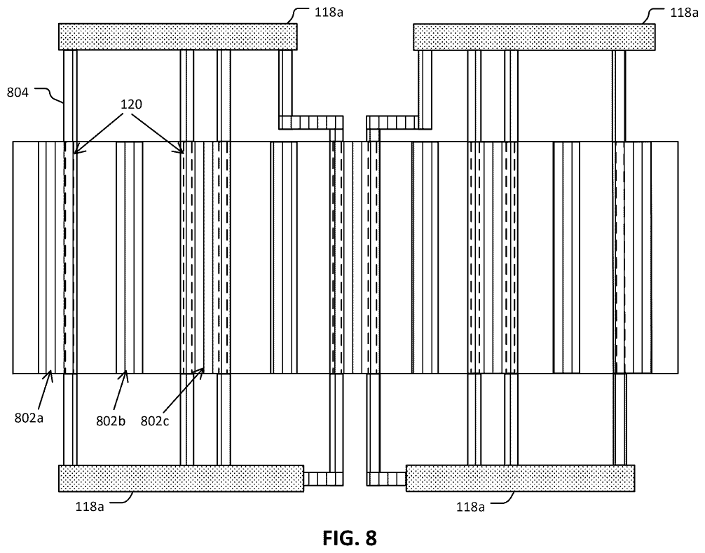

FIGS. 7A and 7B are cross-sectional views of a semiconductor device 100 that are alternative embodiments to the device structure shown in FIG. 1, and FIG. 8 is a plan view showing an example layout of wiring level M2 that may be implemented in accordance with the embodiment of FIG. 7A. FIGS. 7A and 7B do not show heat sinks 134 for ease of illustration, but the backside contacts 130 may be coupled to heat sinks 134 in a similar fashion to the embodiment of FIG. 1.

In FIG. 7A, thermally conductive electrical insulator pillars 120 extend between gate structures 116 and structures, e.g. a metal lines 802, of metal layer M2. The metal lines 802 are coupled to vias 118a, which are in turn coupled to backside contacts 130. The combination of thermally conductive electrical insulator pillars 120, metal lines 802, vias 118a and backside contacts 130 can transfer heat from gate structures 116 outside of the semiconductor device 100. While FIG. 7A shows top metal structures TM and vias 118a coupled to the same backside contacts 130, in another embodiment the vias 118a are coupled to different backside contacts 130 from top metal structures, e.g. backside contacts 130 which are configured for heat transfer. In an embodiment, the vias 118a are copper vias.

When thermally conductive electrical insulator pillars 120 extend between the gate structures 116 and metal lines 802, the pillars may be formed before forming metal level M2. In the embodiment of FIG. 7A, the metal lines 802 are active metal lines, e.g. metal lines that are also coupled to drain regions D of the device.

Turning to FIG. 7B, in another embodiment, thermally conductive electrical insulator pillars 120 extend between gate structures 116 and metal lines of metal layer M1, and the metal lines of metal layer M1 are coupled to metal lines 802 of metal layer M2 by vias 118. The metal lines of metal layer M1 to which the thermally conductive electrical insulator pillars 120 are coupled may be dummy metal lines or active metal lines (e.g. in a configuration similar to that of FIG. 7A). The metal lines 802 are coupled to vias 118a, which are in turn coupled to backside contacts 130. In the embodiment of FIG. 7B, the metal lines 802 may be dummy metal lines.

Other variations of thermal coupling through BEOL metal layers are possible. For example, the metal lines 802 which are coupled to vias 118a may be located in a different metal layer Mn such as metal layer M3 or even metal layer M1. A thermally conductive electrical insulator pillar 120 may be directly coupled to a metal line 802 which is coupled to vias 118a, or indirectly coupled to the terminal metal line 802 by one or more via 118.

In addition, although only one thermally conductive electrical insulator pillar 120 is shown in FIGS. 7A and 7B for each gate structure 116, in other embodiments, two or more thermally conductive electrical insulator pillars 120 may be coupled to each gate structure 116. The two or more thermally conductive insulator pillars 120 may be coupled to active or dummy metal lines.

As seen in FIG. 8, some metal lines 802 have increased widths to accommodate thermally conductive electrical insulator pillars 120. For example, metal line 802a is expanded in the width direction by a width that is greater than the combined width of metal line 802b (which is not coupled to a thermally conductive electrical insulator pillar 120) and a pillar 120. Similarly, metal line 802c, which is coupled to two thermally conductive electrical insulator pillars 120, has a width that is greater than the sum of the width of the two thermally conductive electrical insulator pillars 120 and the width of metal line 802b.

FIG. 8 shows an embodiment in which each gate structure 116 is coupled to a single thermally conductive electrical insulator pillar 120. In an embodiment in which two thermally conductive electrical insulator pillars 120 are coupled to each gate structure 116, e.g. the embodiment of FIGS. 5 and 6, the metal lines 802b may be replaced by wider metal lines 802c to accommodate the additional pillars 120. The metal lines 802a which are coupled to a single thermally conductive electrical insulator pillar 120 may only be present at ends of a block of transistors as shown in the figure.

Also shown in FIG. 8 are metal line portions 804 which extend between the metal lines 802a and 802c which are vertically aligned with gate structures 116. The metal line portions 804 may include lines which run parallel and perpendicular to the metal lines 802, and provide a thermal path between the metal lines 802 and vias 118a. The vias 118a may be electrically inactive (dummy) vias. A different set of contact and via structures (not shown), e.g. active via structures, may be present in addition to dummy vias for providing electrical signals to and from metal lines 802. Accordingly, portions of thermally conductive paths from thermally conductive electrical insulator pillars 120 may be separate from active structures of a device.

The thermally conductive electrical insulator pillars 120 according to embodiments of the present disclosure provide significant advantages to a semiconductor device 100. Because the pillars 120 are electrical insulators, they can be in direct contact with a gate structure 116 without significantly affecting performance. The close proximity to gate structures allows the thermally conductive electrical insulator pillars 120 to remove more heat than conventional thermally conductive structures. Accordingly, heat may be effectively conveyed away from the gate structures 116, and may be conveyed outside of the device 100 leading to additional thermal gains. Moreover, embodiments may be implemented with minimal additional processing steps, thereby reducing fabrication complexity and cost.

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting.

1. A semiconductor device comprising:
a semiconductor substrate;
a gate structure on the semiconductor substrate, the gate structure comprising a source region, a drain region, and a gate electrode; and
at least one thermally conductive electrical insulator pillar in contact with the gate structure,
wherein the at least one thermally conductive electrical insulator pillar extends from the gate structure to a back end of line (BEOL) layer of the semiconductor device.

2. The semiconductor device of claim 1, wherein the gate structure is an asymmetrical gate structure with an extended side, and the at least one thermally conductive electrical insulator pillar includes a first thermally conductive electrical insulator pillar located on the extended side of the gate structure.

3. The semiconductor device of claim 2, wherein the asymmetrical gate structure is at least one of an extended drain metal oxide semiconductor (EDMOS) gate and a lateral double-diffused metal oxide semiconductor (LDMOS) gate, and the first conductive electrical insulator pillar is located on the drain side of the gate structure.

4. The semiconductor device of claim 3, wherein the first thermally conductive electrical insulator pillar contacts at least one of a capping layer, a spacer, and the drain region of the gate structure.

5. The semiconductor device of claim 2, wherein the first thermally conductive electrical insulator pillar contacts a shallow trench isolation structure of the gate structure.

6. The semiconductor device of claim 1, wherein the at least one thermally conductive electrical insulator pillar is formed of at least one of a diamond material, an aluminum oxide and an aluminum nitride.

7. The semiconductor device of claim 1, wherein the at least one thermally conductive electrical insulator pillar contacts a plurality of gate structures.

8. The semiconductor device of claim 1, wherein the gate structure is a symmetrical gate structure, and the at least one thermally conductive electrical insulator pillar includes a first thermally conductive electrical insulator pillar on a drain side of the gate structure and a second thermally conductive electrical insulator pillar on the source side of the gate structure.

9. The semiconductor device of claim 1, wherein the BEOL layer of the semiconductor device is a backend layer at a backside surface of the semiconductor device.

10. The semiconductor device of claim 9, further comprising:
a backside contact at the backside surface of the semiconductor substrate,
wherein the at least one thermally conductive electrical insulator pillar is coupled to the backside contact.

11. The semiconductor device of claim 1, wherein the BEOL layer of the semiconductor device is metal layer M2, the at least one thermally conductive electrical insulator pillar is coupled to a metal line in metal layer M2, and the metal line in metal layer M2 is coupled to an electrically inactive via.

12. The semiconductor device of claim 1, wherein the BEOL layer of the semiconductor device is an active metal line in metal layer M2.

13. The semiconductor device of claim 1, wherein the BEOL layer of the semiconductor device is metal layer M1, the at least one thermally conductive electrical insulator pillar is coupled to a metal line in metal layer M1.

14. The semiconductor device of claim 13, wherein the metal line in metal layer M1 is coupled to a metal line in metal layer M2 by a first via, and the metal line in metal layer M2 is coupled to a backend layer of the semiconductor device by a second via.

15. A semiconductor device comprising:
a semiconductor substrate;
an asymmetric gate structure on the semiconductor substrate, the asymmetric gate structure comprising a gate electrode, a source region on a source side of the gate electrode, and an extended drain region on a drain side of the gate electrode; and
a thermally conductive electrical insulator pillar on the drain side of the gate structure and in contact with the gate structure;
wherein the thermally conductive electrical insulator pillar extends from the gate structure to a back end of line (BEOL) layer of the semiconductor device.

16. The semiconductor device of claim 15, wherein the gate structure is an extended drain metal oxide semiconductor (EDMOS) gate, and the thermally conductive electrical insulator pillar contacts at least one of a capping layer, a spacer, and the drain region of the EDMOS gate.

17. The semiconductor device of claim 15, wherein the gate structure is a lateral double-diffused metal oxide semiconductor (LDMOS) gate, and the thermally conductive electrical insulator pillar contacts a shallow trench isolation structure of the LDMOS gate.

18. The semiconductor device of claim 15, wherein the BEOL layer of the semiconductor device is metal layer M2, the at least one thermally conductive electrical insulator pillar is coupled to a metal line in metal layer M2.

19. A method of forming a semiconductor device, the method comprising:
forming a gate structure on the semiconductor substrate, the gate structure comprising a source region, a drain region, and a gate electrode; and
forming at least one thermally conductive electrical insulator pillar in contact with the gate structure,
wherein the at least one thermally conductive electrical insulator pillar extends from the gate structure to a back end of line (BEOL) layer of the semiconductor device.

20. The method of claim 19, wherein the at least one thermally conductive electrical insulator pillar is formed of at least one of a diamond material, an aluminum oxide and an aluminum nitride.
